(19) United States
(12) Patent Application Publication
(10) Pub. No.: US 2022/0081615 A1
(43) Pub. Date: Mar. 17, 2022

(54) ETCHING COMPOSITION FOR SILICON NITRIDE AND METHOD FOR MANUFACTURING SEMICONDUCTOR DEVICE

(71) Applicant: Kioxia Corporation, Tokyo (JP)

(72) Inventors: Akira ENDO, Inagi (JP); Yasushi NAKASAKI, Yokohama (JP); Masayasu MIYATA, Kawasaki (JP)

(73) Assignee: Kioxia Corporation, Tokyo (JP)

(21) Appl. No.: 17/194,929

(22) Filed: Mar. 8, 2021

(30) Foreign Application Priority Data
Sep. 15, 2020 (JP) 2020-154695

(51) Int. Cl. C09K 13/06; H01L 21/311; H01L 27/11582

(52) U.S. Cl. CPC C09K 13/06; H01L 27/11582; H01L 21/31111

(57) ABSTRACT

An etching composition for silicon nitride includes: a phosphoric acid solution; and an additive containing a silane compound having a composition represented by

General formula: Si(R¹)(R²)(R³)(R⁴)
wherein R¹, R², R³, and R⁴ are monovalent groups, at least one of R¹, R², R³, or R⁴ is an alkoxy group, and at least another one of R¹, R², R³, or R⁴ is a functional group containing two or more oxygen.

### CROSS REFERENCE TO RELATED APPLICATION

This application is based upon and claims the benefit of priority from Japanese Patent Application No. 2020-154695, filed on Sep. 15, 2020; the entire contents of which are incorporated herein by reference.

### FIELD

Embodiments disclosed herein relate to an etching composition for silicon nitride and a method for manufacturing a semiconductor device.

### BACKGROUND

In a method for manufacturing a semiconductor device, a process of selectively etching silicon nitride films is carried out in various processes. For example, in a method for manufacturing a three-dimensional stacked nonvolatile memory device, where memory cells are stacked in three dimensions to achieve high integration of memory devices, the process of selectively etching the silicon nitride films is carried out for a stack formed by alternately stacking silicon oxide films and silicon nitride films. This process is carried out to form a stack where insulating films and conductive films are stacked around a memory hole. In the etching process of the silicon nitride film, it is required to increase an etching rate of the silicon nitride film.

### BRIEF DESCRIPTION OF THE DRAWINGS

FIG. 1A to FIG. 1C are sectional diagrams each illustrating an example of an etching process of silicon nitride using an etching composition of an embodiment.

FIG. 2 is a diagram illustrating a molecular structure of a first example of a silane compound used in the etching composition of the embodiment.

FIG. 3 is a diagram illustrating a molecular structure of a second example of the silane compound used in the etching composition of the embodiment.

FIG. 4 is a diagram illustrating a molecular structure of a third example of the silane compound used in the etching composition of the embodiment.

FIG. 5 is a diagram illustrating a schematic reaction when silicon nitride is etched with an aqueous phosphoric acid solution.

FIG. 6 is a diagram illustrating proceeding of the reaction when silicon nitride is etched with the aqueous phosphoric acid solution.

FIG. 7 is a table listing Eₐ₁, Eₐ₂, Eₐ₁+Eₐ₂, and ΔE_{MO} of the silane compounds used in the etching composition of the embodiment.

FIG. 8 is a diagram illustrating a relationship between ΔE_{MO} and Eₐ₁+Eₐ₂ of the silane compound used in the etching composition of the embodiment.

FIG. 9 illustrates a relationship between an energy level of the lowest unoccupied molecular orbital (LUNO) of a silane compound additive used in the etching composition of the embodiment and Eₐ₁+Eₐ₂.

FIG. 10 is a diagram illustrating a condensing reaction of silica.

FIG. 11 is a diagram illustrating reaction processes of the condensing reaction of silica.

FIG. 12 is a diagram illustrating an etching reaction of silicon oxide.

FIG. 13 is a diagram illustrating reaction processes of the etching reaction of silicon oxide.

FIG. 14 is a table listing Eₐ₃, Eₐ₄, Eₐ₅, and Eₐ₆ of the silane compounds used in the etching composition of the embodiment.

FIG. 15 is a sectional diagram illustrating a semiconductor memory device fabricated by a manufacturing process of a semiconductor device of a second embodiment.

FIG. 16 is a sectional diagram illustrating the manufacturing process of the semiconductor device of the second embodiment.

FIG. 17 is a sectional diagram illustrating the manufacturing process of the semiconductor device of the second embodiment.

FIG. 18 is a sectional diagram illustrating the manufacturing process of the semiconductor device of the second embodiment.

### DETAILED DESCRIPTION

An etching composition for silicon nitride according to an embodiment includes: a phosphoric acid solution; and an additive containing a silane compound having a composition represented by

General formula: Si(R¹)(R²)(R³)(R⁴)

wherein R¹, R², R³, and R⁴ are monovalent groups, at least one of R¹, R², R³, or R⁴ is an alkoxy group, and at least another one of R¹, R², R³, or R⁴ is a functional group containing two or more oxygen.

Hereinafter, an etching composition for silicon nitride and a method for manufacturing a semiconductor device of an embodiment will be described with reference to the drawings. In each embodiment presented below, substantially the same components are denoted by the same reference signs, and a description thereof is sometimes partially omitted. The drawings are schematic, and a relationship between a thickness and a planar size, thickness proportions of the respective portions, and the like are sometimes different from actual ones.

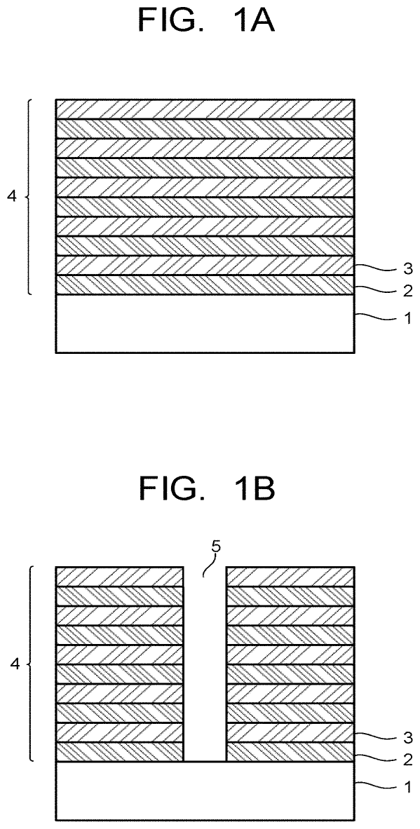

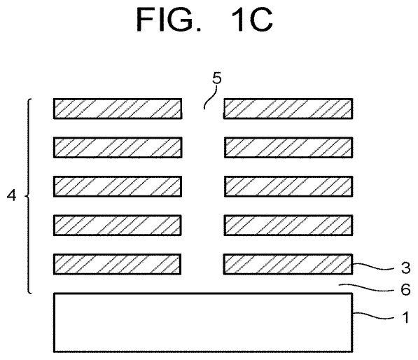

The etching composition for silicon nitride according to the embodiment is used for etching silicon nitride provided on a substrate, such as a semiconductor substrate, for example. FIG. 1A to FIG. 1C are diagrams each illustrate an example of an etching process using the etching composition of the embodiment and illustrate a workpiece to be etched and the etching process. The workpiece illustrated in FIG. 1A is provided on a substrate 1 such as a semiconductor substrate and includes a stack 4 having alternately formed silicon nitride films 2 and silicon oxide films 3. A slit 5 is formed at the stack 4 as illustrated in FIG. 1B, for example. Then, as illustrated in FIG. 1C, the silicon nitride films 2 are selectively etched through the slit 5 to form spaces 6. The etching process of silicon nitride of the embodiment is applied to this kind of etching of the silicon nitride films 2. FIG. 1A to FIG. 1C illustrate an example of the etching process of the embodiment. The etching process of the embodiment is not limited thereto but can be applied to the etching of various silicon nitride materials.

For etching of the silicon nitride films 2 as described above, for example, an aqueous phosphoric acid solution heated to about 150° C. is used. However, the aqueous phosphoric acid solution alone cannot sufficiently increase an etching rate of silicon nitride. Therefore, in the etching process of silicon nitride of the embodiment, an etching composition containing the aqueous phosphoric acid solution and an additive is used. As the aqueous phosphoric acid solution, an aqueous solution of inorganic phosphoric acid (orthophosphoric acid), commonly represented by H₃PO₄, is used. However, instead of or in addition to H₃PO₄, H₄P₂O₇ (pyrophosphoric acid) or other acids may be used. Furthermore, phosphate such as alkali metal salts of phosphoric acid or organic phosphoric acid may be added and used.

The additive contained in the etching composition contains a silane compound having a composition represented by the following general formula.

General formula: Si(R¹)(R²)(R³)(R⁴)

Here, R¹, R², R³, and R⁴ are monovalent groups, at least one of R¹, R², R³, or R⁴ is an alkoxy group, and at least another one of R¹, R², R³, or R⁴ is a functional group containing two or more oxygen. A content of the additive is preferably in a range of 0.01 mass % or more and 15 mass % or less in the aqueous phosphoric acid solution. By adding such an additive to the etching composition, which is mainly constituted by the aqueous phosphoric acid solution, the etching rate of silicon nitride can be increased as described below. Therefore, when selectively etching the silicon nitride films 2 from the stack 4 illustrated in FIG. 1A, it is possible to increase the etching rate of the silicon nitride films 2 to improve productivity and to reduce damage caused by the aqueous phosphoric acid solution on the silicon oxide films 3.

In the silane compound as the additive for the etching composition of the embodiment, at least one of the four monovalent groups bonded to a Si atom, that is, the R¹ group, the R² group, the R³ group, and the R⁴ group, is the alkoxy group, and at least another one is the functional group containing two or more oxygen (hereinafter, sometimes referred to as an oxygen-containing functional group). The silane compound as the additive is alkoxysilane, containing one or more and three or less alkoxy groups, and can be any of Si(OCₙH_{2nA+1})₃R, Si(OCₙH2ₙ₊₁)₂R₂, or Si(OCₙH₂ₙ₊₁)₁R₃ (where n is a number of 1 or more and R is the monovalent group containing at least one oxygen-containing functional group). The alkoxy group contained in alkoxysilane includes a methoxy group, an ethoxy group, a propoxy group, a butoxy group, or the like, but the methoxy group (—OCH₃) is common.

Of the above four R¹, R², R³, and R⁴ groups, a monovalent group other than at least one alkoxy group and at least one oxygen-containing functional group or sulfur-containing functional group are not particularly limited. An alkyl group represented by —CₙH₂ₙ₊₁ (n is a number of 1 or more, for example, an integer number from 1 to 4) is used or a hydroxy group (—OH) or hydrogen (H) may be used. Alkoxysilane represented by “Si(R¹)(R²)(R³)(R⁴)” is preferably trialkoxysilane containing the oxygen-containing functional group, alkyl dialkoxysilane containing the oxygen-containing functional group, dialkyl alkoxysilane containing the oxygen-containing functional group, and the like.

The oxygen-containing functional group bonded to Si in alkoxysilane is not particularly limited as long as it is the functional group containing two or more oxygen but can include, for example, a group containing carboxylic anhydride (hereinafter, sometimes referred to as a first functional group), and a group containing an epoxy group and ether oxygen that is not included in the epoxy group (hereinafter, sometimes referred to as a second functional group). An example of the first functional group includes a group containing the monovalent group represented by the following formula (1). An example of the second functional group includes a group containing the monovalent group represented by the following formula (2).

General formula: R⁵(OC)O(CO)R⁶ (1)

Here, R⁵ and R⁶ each exist independently and R⁵ is a monovalent organic group and R⁶ is a divalent organic group, or R⁵ and R⁶ are an organic group forming a cyclic compound having a ring structure selected from the group consisting of an alicyclic structure, an aromatic ring structure, and a complex ring structure combining them.

General formula: R⁷OR⁸—O— (2)

Here, R⁷ is a divalent organic group and R⁸ is a trivalent organic group.

A concrete example of the first functional group includes the monovalent group represented by the following formula (3).

General formula: (CHₐ)ₓ₁(CO)_{y1}O_{w1}(CH_{b})_{z1} (3)

Here, x1, y1, z1, w1, a, and b are numbers satisfying x1≥1, y1≥2, z1≥1, w1≥1, a≥1, and b≥0.

The CHₐ group and the CH_{b} group may each exist independently to form a chain compound, or the CHₐ group and the CH_{b} group may be the group forming the cyclic compound having the ring structure selected from the group consisting of the alicyclic structure, the aromatic ring structure, and the compound ring structure combining them.

A concrete example of the second functional group is the monovalent group represented by the following formula (4).

General formula: (H₂ₙCₙ)ₓ₂O(CH)_{y2}(CH₂)_{z2}—O_{w2}— (4)

Here, x2, y2, z2, w2, and n are numbers satisfying x2≥1, y2≥1, z2≥1, w2≥1, and n≥1.

The monovalent group based on carboxylic anhydride in the first functional group may be contained as it is, but the monovalent group partly having a carboxylic anhydride structure is preferably contained, such as the monovalent group based on succinic anhydride (C₄H₄O₃) (—C₄H₄O₃: in the formula (3), the monovalent group where a=2, x1=1, y1=2, b=1, z1=1, w1=1), the monovalent group based on maleic anhydride (C₄H₂O₃) (—C₄H₁O₃: in the formula (3), the monovalent group where a=1, x1=1, y1=2, b=0, z1=1, w1=1), and the monovalent group based on phthalic anhydride (C₈H₄O₃) (—C₈H₃O₃: in the formula (3), the monovalent group where a=1, x1=3, y1=2, b=0, z1=3, w1=1).

Furthermore, the monovalent group based on carboxylic anhydride is not limited to the monovalent cyclic compound, but may also be the monovalent chain compound represented by the following formula (5).

General formula: R⁹(CO)O(CO)R¹⁰ (5)

Here, R⁹ is the monovalent group such as the alkyl group or a phenyl group, and R¹⁰ is a divalent group such as an alkylene group or a phenylene group.

Concrete examples of such a monovalent group include the monovalent group based on acetic anhydride (C₄H₆O₃) (—C₄H₅O₃: in the formula (3), the monovalent group where a=3, x1=1, y1=2, b=2, z1=1, w1=1), the monovalent group based on benzoic anhydride (C₁₄H₁₀O₃) (—C₁₄H₉O₃: in the formula (3), the monovalent group where a=1, x1=9, y1=2, b=0, z1=3, w1=1), and so on.

The monovalent group having the carboxylic anhydride structure may be bonded to Si as it is, but it is preferably bonded to Si with, for example, the divalent group based on the alkylene group represented by —(CₙH₂ₙ)— or the carboxylic acid such as —C(═O)O— therebetween. The divalent groups interposed between the monovalent group having the carboxylic anhydride structure and Si are not limited to these. In the alkylene group interposed between the monovalent group having the carboxylic anhydride structure and Si, n is preferably a number from 1 to 4.

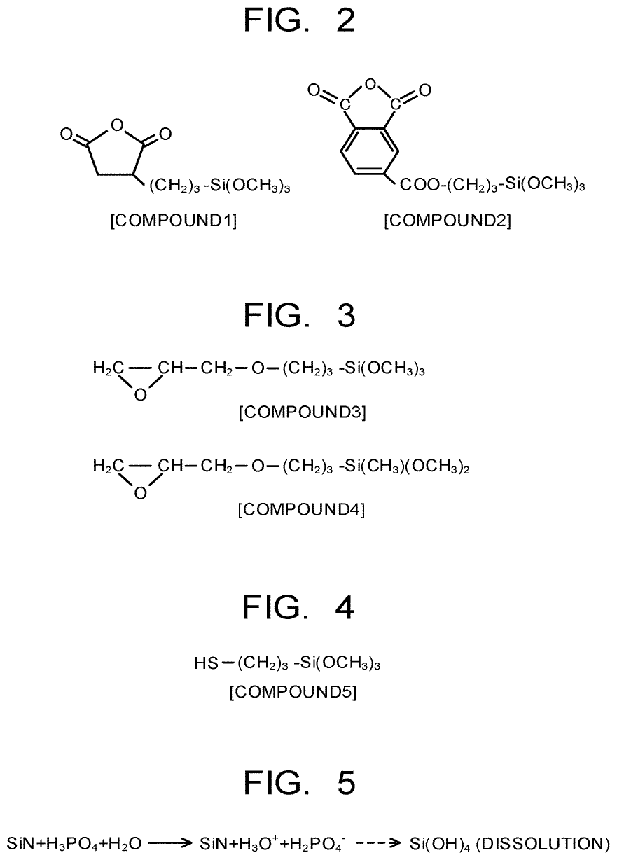

Concrete examples of the silane compounds containing the first functional group include 3-trimethoxysilylpropylsuccinic anhydride and 3-trimethoxysilylpropyltrimellitic anhydride. 3-Trimethoxysilylpropylsuccinic anhydride (Compound 1) is represented by a chemical formula: C₁₀H₁₈O₆Si, and its structural formula is illustrated in FIG. 2. 3-Trimethoxysilylpropyltrimellitic anhydride (Compound 2) is represented by a chemical formula C₁₅H₁₈O₈Si, and its structural formula is illustrated in FIG. 2. These silane compounds improve the etching rate of silicon nitride by the aqueous phosphoric acid solution based on the functional groups or the like containing two or more oxygen, and further, inhibits condensation of the silica and etching of the silicon oxide (silicon oxide film).

Concrete examples of the formula (4) include the monovalent group having a glycidyl group or the like where the alkylene group such as —CH₂— is bonded to the epoxy group represented by (H₂C)O(CH), and further, the glycidyl group or the like is bonded to ether oxygen (—O—). However, the groups included in the formula (4) are not limited to the glycidyl group, and the alkylene group represented by —(CₙH₂ₙ)—, preferably the alkylene group where n is a number in the range of 1 to 4, may be bonded to the epoxy group. It may also have a structure in which another alkylene group or alkyl group is bonded to CH₂ forming the epoxy group, such as the structure represented by, for example, H₃C—(CₙH₂ₙ)—(HC)O(CH)—.

Concrete examples of the silane compounds containing the second functional group include 3-glycidoxypropyltrimethoxysilane and 3-glycidoxypropylmethyldimethoxysilane, for example. 3-Glycidoxypropyltrimethoxysilane (Compound 3) is represented by a chemical formula: C₉H₂₀O₅Si, and its structural formula is illustrated in FIG. 3. 3-Glycidoxypropylmethyldimethoxysilane (Compound 4) is represented by a chemical formula: C₉H₂₀O₄Si, and its structural formula is illustrated in FIG. 3. These compounds improve the etching rate of silicon nitride by the aqueous phosphoric acid solution based on the functional group or the like containing two or more oxygen, and further, inhibits condensation of the silica and etching of the silicon oxide (silicon oxide film).

The etching composition may comprises a second additive containing a silane compound having a composition represented by the following general formula.

General formula: Si(R¹¹)(R¹²)(R¹³)(R¹⁴)

Here, R¹¹, R¹², R¹³, and R¹⁴ are monovalent groups, at least one of R¹¹, R¹², R¹³, or R¹⁴ is an alkoxy group, and at least another one of R¹¹, R¹², R¹³, or R¹⁴ is a functional group containing one or more sulfur.

The functional group containing one or more sulfur (hereinafter, sometimes referred to as a sulfur-containing functional group) bonded to Si in alkoxysilane is not particularly limited as long as it is the functional group containing one or more sulfur but can include, for example, a group containing a thiol group (—SH) (hereinafter, sometimes referred to as a third functional group). An example of the third functional group includes a group containing the monovalent group represented by the following formula (6).

General formula: (HS)ₓ₃(CH_{c})(CH₂)_{y2}— (6)

Here, x3, y3, and c are numbers satisfying x3≥1, y3≥1, and c≥0.

Concrete examples of the silane compounds containing the third functional group include 3-mercaptopropyltrimethoxysilane. 3-Mercaptopropyltrimethoxysilane (Compound 5) is represented by a chemical formula: C₆H₁₆O₃SSi, and its structural formula is illustrated in FIG. 4. This silane compound improves the etching rate of silicon nitride by the aqueous phosphoric acid solution based on the functional groups or the like containing one or more sulfur, and further, inhibits condensation of the silica and etching of the silicon oxide (silicon oxide film).

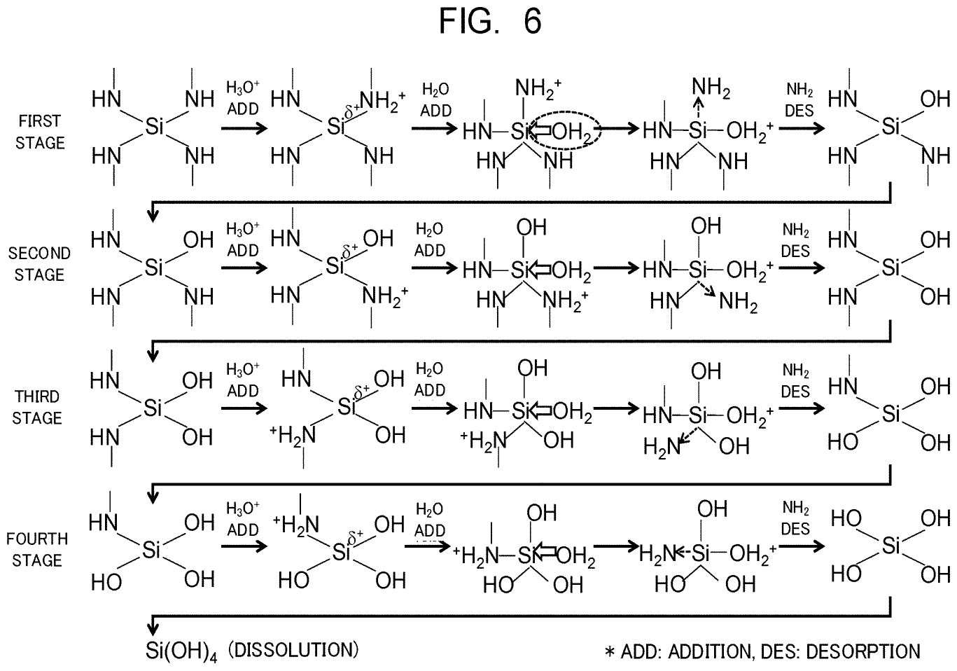

Next, an etching process of silicon nitride (SiN) with the etching composition will be described in detail. First, the etching of SiN with the aqueous phosphoric acid solution is described with reference to FIG. 5 and FIG. 6. As illustrated in the schematic reaction equation in FIG. 5, the etching of SiN with an aqueous H₃PO₄ solution proceeds by a reaction of H₃PO₄ with H₂O to produce a hydronium ion (H₃O⁺), which is added to SiN. Concretely, the etching of SiN proceeds based on the reaction equation illustrated in FIG. 6. In FIG. 6, the arrows and the hooked arrows indicate the direction of the reaction proceeding. In addition, the short leftward hollow arrows and the dashed arrows in FIG. 6 indicate the direction where H₂O attacks Si and the desorption of NH₂, respectively.

As illustrated in FIG. 6, one of —NH— groups bonded to Si becomes —NH₂⁺— by adding the hydronium ion. Then, —OH₂⁺— is added to Si by adding H₂O, further NH₂ is desorbed, and the state where one —OH is bonded to Si is obtained. Here, the first stage in FIG. 6 represents the addition reaction of the first H₂O, the second stage represents the addition reaction of the second H₂O, the third stage represents the addition reaction of the third H₂O, and the fourth stage represents the addition reaction of the fourth H₂O. These reactions proceed in order for four —NH— groups bonded to Si, and finally, SiN is dissolved as Si(OH)₄, and the etching proceeds.

In the reaction process of SiN with the aqueous phosphoric acid solution, it was found that the formation process of the five-coordinated state of Si by the addition of the first water was the rate-determining step of the etching reaction of SiN. Concretely, it is the addition reaction of H₂O in the first stage of the reaction process illustrated in FIG. 6 (dotted circle in FIG. 6). Therefore, if it is possible to add a proton to the NH₂ group on the SiN surface and to lower activation energy of the water addition reaction to Si, the etching rate of SiN can be increased. Considering this point, to enhance the formation of the five-coordinated state of Si, the use of an additive with (1) low activation energy (Eₐ₁) of the proton formation process of SiN and (2) low activation energy (Eₐ₂) of the addition process of a water molecule to Si followed by (1) enables to easily form the five-coordinated state of Si and increase the etching rate of SiN. Concretely, when alkoxysilanes with the activation energies Eₐ₁, Eₐ₂, and their sumation (Eₐ₁+Eₐ₂) lower than those of H₃O⁺ at least when the alkoxysilanes with the lower Eₐ₂ and Eₐ₁+Eₐ₂ than those of H₃O⁺ are used as the additive, the etching rate of SiN can be increased.

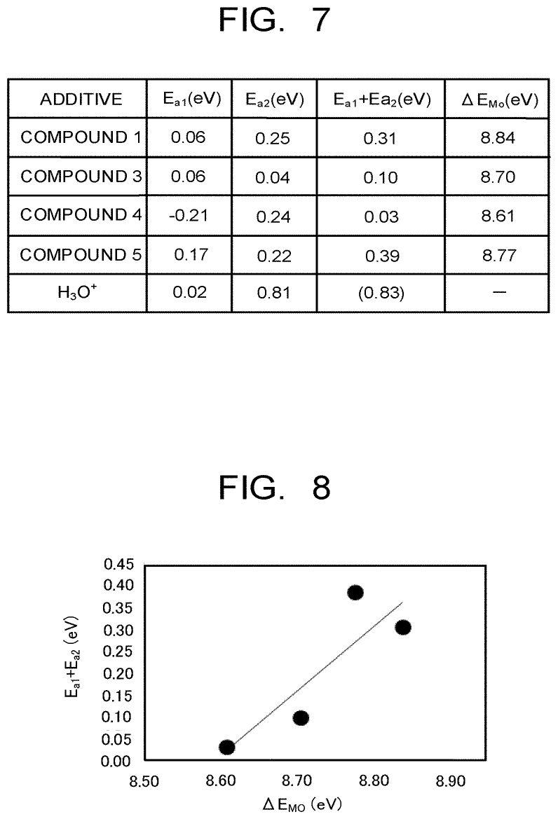

Regarding the above-mentioned additive that increases the etching rate of SiN, it was found that alkoxysilane with the functional group containing two or more oxygen was effective. The activation energies Eₐ₁, Eₐ₂, and their summation (Eₐ₁+Eₐ₂) of each of Compound 1, Compound 3, Compound 4, and Compound 5, which are described as the concrete examples of alkoxysilane as the additive in the embodiment, and H₃O⁺ are listed in FIG. 7. As listed in FIG. 7, Eₐ₁ of H₃O⁺ is 0.02 eV, Eₐ₂ is 0.81 eV, and Eₐ₁+1Eₐ₂ is 0.83 eV, while Eₐ₂ and Eₐ₁+Eₐ₂ of each of Compound 1, Compound 3, Compound 4, and Compound 5 are all lower than those of H₃O⁺. The addition reaction of a proton to the —NH₂ group on the SiN surface proceeds and the formation process of the five-coordinated state of Si proceeds easily by using Compound 1, Compound 3, Compound 4, or Compound 5 as the additive. Therefore, the etching rate of SiN can be increased.

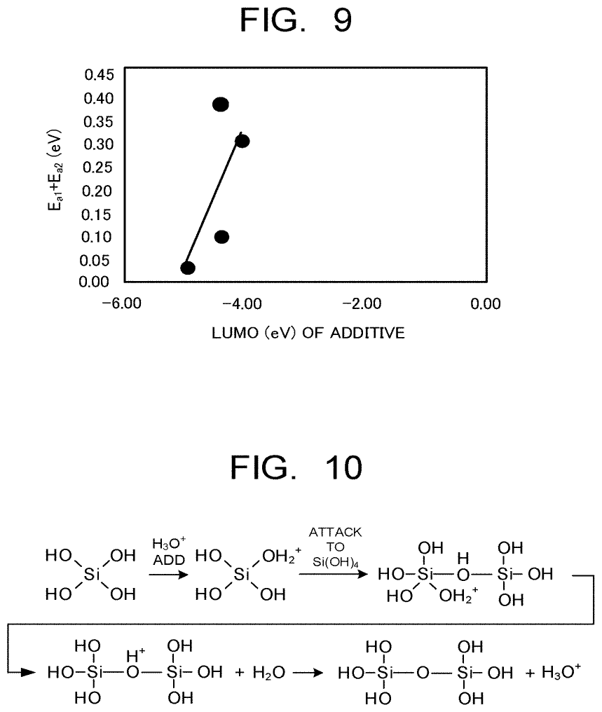

The above phenomenon is also evident from ΔE_{MO} of the additive. Here, ΔE_{MO} is the value expressed as “(energy level of the lowest unoccupied molecular orbital (LUMO) of the protonated state of SiN by the additive)—(energy level of the highest occupied molecular orbital (HOMO) of water molecules)”. FIG. 7 lists ΔE_{MO} of each of Compound 1, Compound 3, Compound 4, and Compound 5 together. FIG. 8 illustrates the relationship between ΔE_{MO} and Eₐ₁+Eₐ₂. The protonated state of SiN by the additive, which shows lower ΔE_{MO}, is able to be undergone the nucleophilic addition of water molecules. Such the additive also tends to form the five-coordinated state of Si. Furthermore, FIG. 9 illustrates the relationship between the LUMO of the additive and Eₐ₁+Eₐ₂, which shows that the deeper (smaller) LUMO of the additive corresponds to the lower Eₐ₁+Eₐ₂. Therefore, the five-coordinated state of Si is easily formed. From these points, the etching rate of SiN can be increased by using Compound 1, Compound 3, Compound 4, and Compound 5 as the additive. These phenomena are not limited to Compound 1, Compound 3, Compound 4, and Compound 5, but can also be expected for Compound 2 and other alkoxysilanes with the functional group containing two or more oxygen or the functional group containing one or more sulfur.

When the aqueous phosphoric acid solution containing the above-mentioned additive is used at a temperature of about 150° C., and the silicon nitride films 2 are selectively etched through the slit 5 as illustrated in FIG. 1B and FIG. 1C, it is confirmed that the etching rate of the silicon nitride films 2 is improved compared to the etching using only the aqueous phosphoric acid solution. Therefore, as illustrated in FIG. 1A, the etching composition of the embodiment is useful in the case of selective etching of the silicon nitride films 2 for the stack 4 having the silicon nitride films 2 and the silicon oxide films 3. It is possible to etch the silicon nitride films 2 efficiently while maintaining states of the silicon oxide films 3.

Next, in the etching process of the silicon nitride (SiN) with the above-mentioned etching compositions, the suppressive effect on a condensation reaction and an etching reaction of the silicon oxide (SiO) will be described in detail. When the silicon nitride (SiN) films are etched selectively by subjecting etching process to the stack 4 having the silicon nitride films 2 and the silicon oxide films 3 as shown in FIG. 1A to FIG. 1C, the condensation reaction and the etching reaction of the silicon oxide (SiO) which cause as a side reaction of the etching reaction of the SiN disturb the selective etching reaction of SiN. These reactions are described with reference to FIG. 10 to FIG. 13.

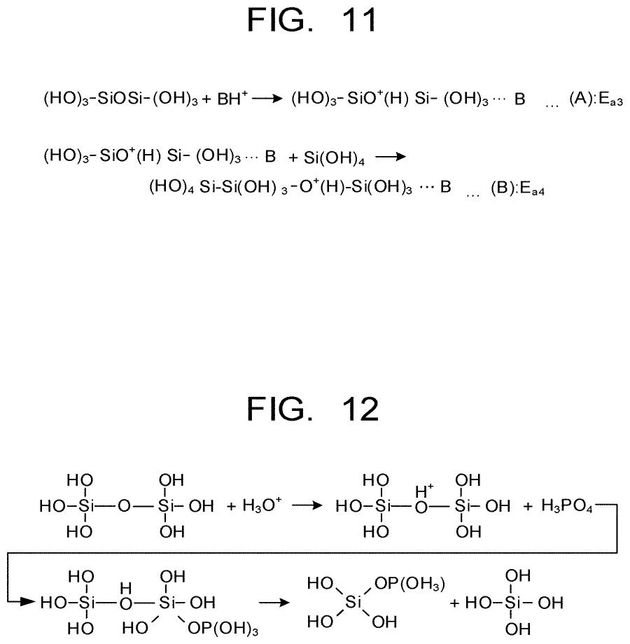

Regarding the condensation reaction of the silicon oxide (SiO), as shown in the schematic reaction equation in FIG. 10, it is thought that the reaction occurs by dehydration condensation of the silicic acid (Si(OH)₄) which is one of the products of the etching reaction of the SiN, the silica (in-liquid silica) melted preliminarily into the phosphoric acid solution, the silicic acid (Si(OH)₄) formed by the etching reaction of the silicon oxide films 3 and so on. In the condensation reaction of the silica (SiO), the protonated additive (BH⁺) gives a proton to the oxygen atom in the siloxane bond of a silicate dimer ((HO)₃—SiOSi—(OH)₃), as shown in the reaction formula (A) of FIG. 11 (reaction 1). In FIG. 11, Ea3 is the activation energy of the reaction 1. As shown in the reaction formula (B) of FIG. 11, a Si(OH)₄ attacks to one of the Si atoms in the reaction product of the reaction 1 in the nucleophilic manner, and thereby, the second siloxane bond is formed (reaction 2). In FIG. 11, Ea4 is the activation energy of the reaction 2. In this way, the condensation reaction of the silica progresses.

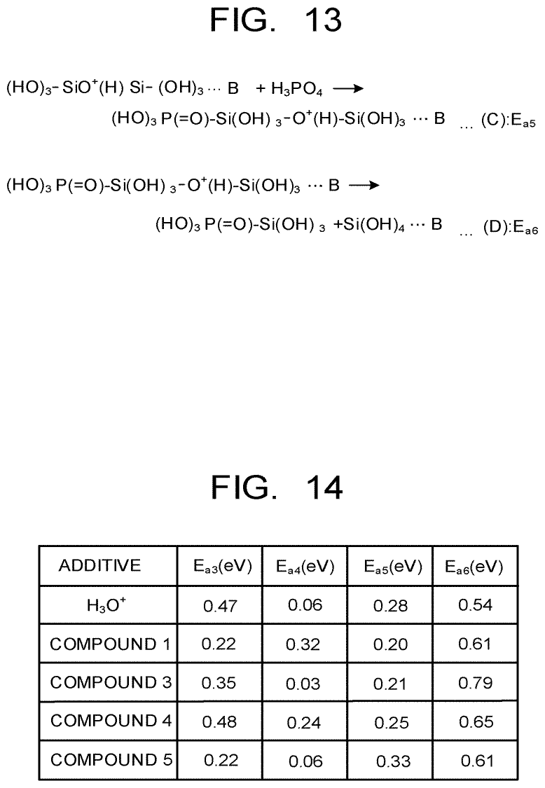

Regarding the etching reaction of the silicon oxide film (SiO film), as shown in the schematic reaction equation in FIG. 12, it is thought that the reaction is caused by addition of H₃O⁺ to silica (SiO) and subsequent addition of the water molecule. It is thought that the reaction progresses by the addition of not only the water molecule but also H₃PO₄. In the etching reaction of the silica (SiO), first, the reaction 1 as shown in the reaction formula (A) in FIG. 11 is occurred. Followed by this reaction 1, as shown in the reaction formula (C) in FIG. 13, H₃PO₄ attacks to one of Si atoms in the reaction product of the reaction 1 in the nucleophilic manner (reaction 3). In FIG. 13, Ea5 is the activation energy of the reaction 3. The reaction product of the reaction 3 dissociates into Si(OH)₄ and (HO)₃P(═O)—Si(OH)₃ (reaction 4), which is shown in the reaction formula (D) in FIG. 13. In FIG. 13, Ea6 is the activation energy of the reaction 4. In this way, the etching reaction of the silica progresses.

The activation energies Ea3, Ea4, Ea5, and Ea6 of Compound 1, Compound 3, Compound 4, and Compound 5 are listed in FIG. 14. It is thought that Compound 1, Compound 3, Compound 4, and Compound 5 contribute to suppress the condensation reaction and the etching reaction of the silica based on the activation energies. The Compound 1 and Compound 4 are effective for the suppression of the condensation reaction of the silica. The Compound 3, Compound 4, Compound 5, and Compound 1 are effective in this order to suppress the etching reaction of the silicon oxide films (SiO films) by H₃PO₄. Further, an example of the compound for the suppression of each of the condensation reaction and the etching reaction of the silica includes Compound 1 and Compound 4 which have higher activation energies Ea4 and Ea6.

Thus, by using Compound 1, Compound 3, Compound 4, and Compound 5 as the additive, the condensation reaction and the etching reaction of the silica can be inhibited. Therefore, the selective etching and etching rate of the SiN can be enhanced. These phenomena are not limited to Compound 1, Compound 3, Compound 4, and Compound 5, but can also be expected for Compound 2 and the other alkoxysilanes with the functional group containing two or more oxygen or the functional group containing one or more sulfur.

### Second Embodiment

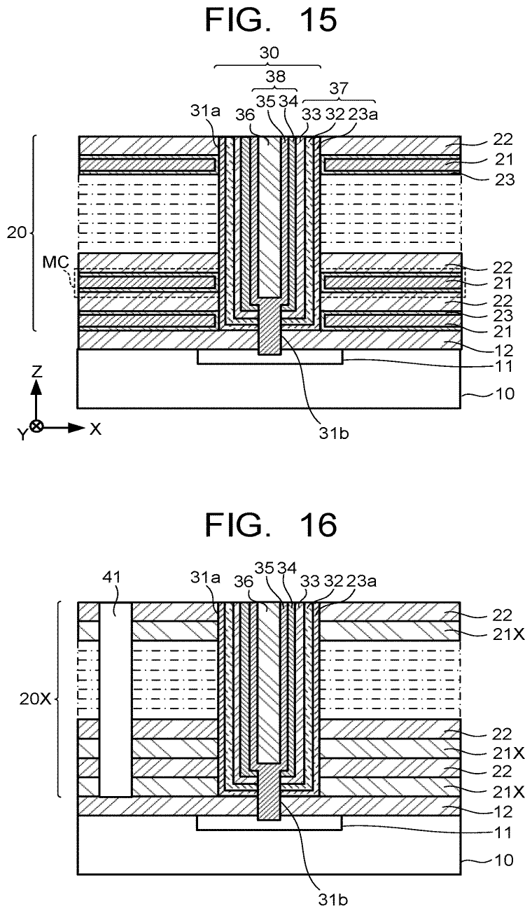

Next, a second embodiment where a manufacturing method of an embodiment is applied to manufacturing of, for example, a semiconductor memory device having a memory cell array, will be described with reference to FIG. 15 to FIG. 18. FIG. 15 is a sectional diagram illustrating a memory cell in the semiconductor memory device fabricated by applying the manufacturing method of the second embodiment. FIG. 16 to FIG. 18 are diagrams illustrating manufacturing processes of the semiconductor memory device illustrated in FIG. 15. The semiconductor memory device illustrated in FIG. 15 includes a semiconductor substrate 10, a stack 20 provided on the semiconductor substrate 10, and a columnar portion 30 extending along a stacking direction of the stack 20. In FIG. 15, two directions parallel to a main surface of the semiconductor substrate 10 and intersecting each other are an X-direction and a Y-direction, and a direction intersecting both of these X- and Y-directions is a Z-direction (stacking direction).

The semiconductor substrate 10 has a diffusion layer 11 that is connected to a selection transistor. On the semiconductor substrate 10 having the diffusion layer 11, the stack 20 is provided with an interlayer insulating film 12 therebetween. The stack 20 has a plurality of conductive films 21 and a plurality of insulating films 22. These conductive films 21 and insulating films 22 are stacked alternately in the Z-direction. As the conductive film 21, tungsten (W) or molybdenum (Mo) with a film thickness of about 30 nm is used, as will be described in detail later. As the insulating film 22, a silicon oxide film with a film thickness of about 30 nm is used. An aluminum oxide film is formed around each conductive film 21 as a block insulating film 23.

The conductive film 21 is formed by alternately stacking silicon oxide films as the insulating films 22 and silicon nitride films, selectively etching the silicon nitride films, then after forming the aluminum oxide film 23 on each of wall surfaces of spaces where the silicon nitride films are etched away, filling the remaining spaces with W or Mo by a CVD method, an ALD method, or the like, as described below.

The columnar portion 30 is provided to penetrate the stack 20 in the Z-direction and has an outer peripheral portion 31a. The columnar portion 30 is formed to reach the diffusion layer 11 provided on the semiconductor substrate 10. The columnar portion 30 has a MONOS (metal-oxide-nitride-oxide-silicon) structure. That is, along the outer peripheral portion 31a of the columnar portion 30, there are formed a silicon oxide film 23a as part of the block insulating film, a silicon nitride film as a charge storage film 32, a silicon oxide film as a tunnel insulating film 33, and a silicon film as a channel film 34, in order from the stack 20 side.

A silicon film 35 is formed on an inside of the channel film 34, and a silicon oxide film 36 is formed on an inside of the silicon film 35. The silicon film 35 has a protruding portion 31b extending toward the Z-direction to take an electrical connection of the channel film 34 to the diffusion layer 11. The charge storage film 32 and the tunnel insulating film 33 form a memory film 37. The channel film 34 and the silicon film 35 form a semiconductor film 38.

The conductive film 21, the block insulating film 23, the memory film 37, and the semiconductor film 38 form a plurality of memory cells MC lined up in the Z-direction. The memory cell MC has a vertical transistor structure where the semiconductor film 38 is surrounded by the conductive film 21 with the memory film 37 therebetween. The semiconductor film 38 functions as a channel of the memory cell MC having the vertical transistor structure, and the conductive film 21 functions as a control gate (control electrode). The charge storage film 32 functions as a data storage layer that stores electric charges injected from the semiconductor film 38.

Next, the method for manufacturing the semiconductor device according to the second embodiment will be described with reference to FIG. 16 to FIG. 18. First, as illustrated in FIG. 16, silicon nitride films 21X each with a film thickness of about 30 nm and silicon oxide films 22 each with a film thickness of about 30 nm as the insulating films 22 are alternately deposited by the CVD method to form a stack 20X on the semiconductor substrate 10 having the diffusion layer 11 with the interlayer insulating film 12 therebetween. The silicon nitride films 21X and the insulating films 22 are each deposited in 100 layers, for example. A memory hole 31a is formed in the stacking direction (Z-direction) of the stack 20X using a lithography method. A diameter of the memory hole 31a is 80 nm, for example.

Next, in the memory hole 31a, there are deposited the silicon oxide film 23a with a film thickness of about 5 nm as part of the block insulating film, the silicon nitride film with a film thickness of about 5 nm as the charge storage film 32, the silicon oxide film with a film thickness of about 8 nm as the tunnel insulating film 33, a polysilicon film with a film thickness of about 5 nm as the channel film 34, and a silicon oxide film with a film thickness of about 5 nm as a sidewall film (not illustrated) in order. Using the sidewall film as a mask, a lower portion of each of the films 23a, 32, 33, and 34 and the interlayer insulating film 12 are etched by an RIE (reactive ion etching) method to expose the diffusion layer 11. Then, the sidewall film as the mask is etched by the selective RIE to expose the channel film (polysilicon film) 34. Along an inner wall of the channel film 34, the polysilicon film 35 is deposited to electrically connect the channel film 34 to the diffusion layer 11. The silicon oxide film 36 is embedded in a hole that exists inside the polysilicon film 35. Using the lithography and RIE methods, a slit 41 is formed in the stack 20X.

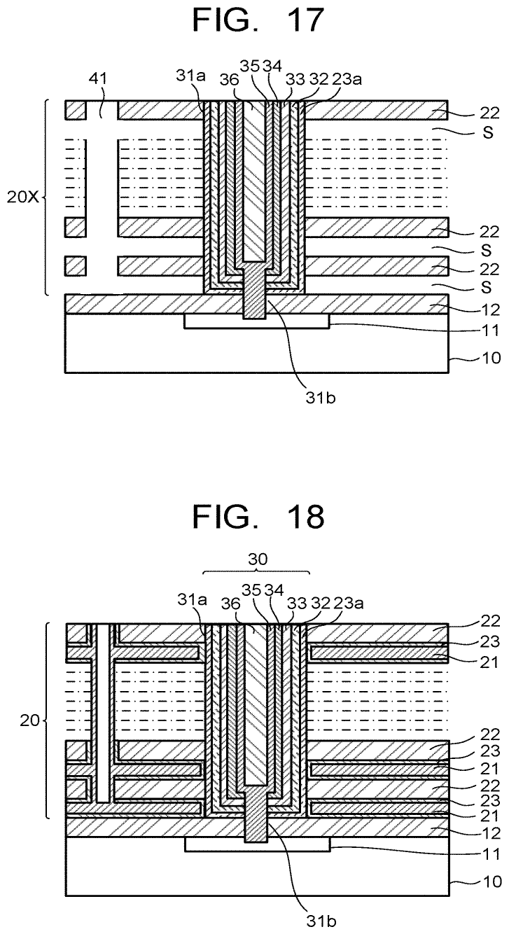

Next, as illustrated in FIG. 17, an etching composition containing phosphoric acid and an additive heated to 150° C. is used to etch the silicon nitride films 21X through the slit 41 to form spaces (filling spaces) S where the conductive films 21 are formed. The etching process of the silicon nitride films 21X is carried out in the same way as in the first embodiment, using the etching composition containing phosphoric acid and the additive containing the predetermined silane compound. As illustrated in FIG. 18, after forming aluminum oxide films each with a film thickness of about 5 nm as the block insulating films 23 on wall surfaces of the spaces S, the spaces S are each filled with a metal film such as a W film or a Mo film, and the conductive films 21 are formed to make the stack 20. Thereafter, the metal films at unnecessary portions are removed, the silicon oxide films are embedded, and upper wiring, and the like, omitted from the illustration, are formed to fabricate a semiconductor device (three-dimensional stacked nonvolatile memory device).

Note that the above-described configurations in the embodiments are applicable in combination, and parts thereof are also replaceable. While certain embodiments have been described, these embodiments have been presented by way of example only, and are not intended to limit the scope of the inventions. Indeed, those embodiments may be embodied in a variety of other forms; furthermore, various omissions, substitutions, and changes in the form of the embodiments described herein may be made without departing from the spirit of the inventions. The accompanying claims and their equivalents are intended to cover such forms or modifications as would fall within the scope and spirit of the inventions.

What is claimed is:

1. An etching composition for silicon nitride, comprising:
a phosphoric acid solution; and
an additive containing a silane compound having a composition represented by
General formula: Si(R¹)(R²)(R³)(R⁴)
wherein R¹, R², R³, and R⁴ are monovalent groups, at least one of R¹, R², R³, or R⁴ is an alkoxy group, and at least another one of R¹, R², R³, or R⁴ is a functional group containing two or more oxygen.

2. The etching composition according to claim 1, wherein
the functional group containing two or more oxygen is a monovalent group containing carboxylic anhydride or a monovalent group containing an epoxy group and ether oxygen not contained in the epoxy group.

3. The etching composition according to claim 1, wherein
the functional group containing two or more oxygen contains a monovalent group having a composition represented by
General formula: R⁵(OC)O(CO)R⁶ (1)
wherein, R⁵ and R⁶ each exist independently, and R⁵ is a monovalent organic group and R⁶ is a divalent organic group, or R⁵ and R⁶ are an organic group forming a cyclic compound having a ring structure selected from the group consisting of an alicyclic structure, an aromatic ring structure, and a complex ring structure combining them, or
General formula: R⁷OR⁸—O— (2)
wherein, R⁷ is a divalent organic group and R⁸ is a trivalent organic group.

4. The etching composition according to claim 1, wherein
the functional group containing two or more oxygen contains a monovalent group having a composition represented by
General formula: (CHₐ)ₓ₁(CO)_{y1}O_{w1}(CH_{b})_{z1}— (3)
wherein, x1, y1, z1, w1, a, and b are numbers satisfying x1≥1, y1≥2, z1≥1, w1≥1, a≥1, and b≥0, and a CHₐ group and a CH_{b} group each exist independently to form a chain compound, or the CHₐ group and the CH_{b} group are a group forming a cyclic compound having a ring structure selected from the group consisting of an alicyclic structure, an aromatic ring structure, and a compound ring structure combining them, or
General formula: (H₂ₙCₙ)ₓ₂O(CH)_{y2}(CH₂)_{z2}—O_{w2}— (4)
wherein, x2, y2, z2, w2, and n are numbers satisfying x2≥1, y2≥1, z2≥1, w2≥1, and n≥1.

5. The etching composition according to claim 1, further comprising a second additive containing a silane compound having a composition represented by
General formula: Si(R¹¹)(R¹²)(R¹³)(R¹⁴)
wherein R¹¹, R¹², R¹³, and R¹⁴ are monovalent groups, at least one of R¹¹, R¹², R¹³, or R¹⁴ is an alkoxy group, and at least another one of R¹¹, R¹², R¹³, or R¹⁴ is a functional group containing one or more sulfur.

6. The etching composition according to claim 5, wherein
the functional group containing one or more sulfur is a monovalent group containing a thiol group.

7. The etching composition according to claim 5, wherein
the functional group containing one or more sulfur contains a monovalent group having a composition represented by
General formula: (HS)ₓ₃(CH_{c})(CH₂)_{y3}— (3)
wherein, x3, y3, and c are numbers satisfying x3≥1, y3≥1, and C≥0.

8. The etching composition according to claim 1, wherein
a monovalent group other than the alkoxy group and the functional group containing two or more oxygen among the R¹, R², R³, and R⁴ is a group selected from the group consisting of an alkyl group, a hydroxyl group, or hydrogen.

9. The etching composition according to claim 1, wherein
the silane compound contains 3-trimethoxysilylpropylsuccinic anhydride, 3-trimethoxysilylpropyltrimellitic anhydride, 3-glycidoxypropyltrimethoxysilane, or 3-glycidoxypropylmethyldimethoxysilane.

10. The etching composition according to claim 5, wherein
the silane compound of the second additive contains 3-mercaptopropyltrimethoxysilane.

11. A method for manufacturing a semiconductor device comprising etching a film containing silicon nitride with an etching composition, wherein
the etching composition contains a phosphoric acid solution; and
an additive containing a silane compound having a composition represented by
General formula: Si(R¹)(R²)(R³)(R⁴)
wherein R¹, R², R³, and R⁴ are monovalent groups, at least one of R¹, R², R³, or R⁴ is an alkoxy group, and at least another one of R¹, R², R³, or R⁴ is a functional group containing two or more oxygen.

12. The method according to claim 11, wherein
the functional group containing two or more oxygen is a monovalent group containing carboxylic anhydride or a monovalent group containing an epoxy group and ether oxygen not contained in the epoxy group.

13. The method according to claim 11, wherein
the functional group containing two or more oxygen contains a monovalent group having a composition represented by
General formula: R⁵(OC)O(CO)R⁶ (1)
wherein, R⁵ and R⁶ each exist independently, and R⁵ is a monovalent organic group and R⁶ is a divalent organic group, or R⁵ and R⁶ are an organic group forming a cyclic compound having a ring structure selected from the group consisting of an alicyclic structure, an aromatic ring structure, and a complex ring structure combining them, or
General formula: R⁷OR⁸—O— (2)
wherein, R⁷ is a divalent organic group and R⁸ is a trivalent organic group.

14. The method according to claim 11, wherein
the functional group containing two or more oxygen contains a monovalent group having a composition represented by
General formula: (CHₐ)ₓ₁(CO)_{y1}O_{w1}(CH_{b})_{z1}— (3)
wherein, x1, y1, z1, w1, a, and b are numbers satisfying x1≥1, y1≥2, z1≥1, w1≥1, a≥1, and b≥0, and a CHₐ group and a CH_{b} group each exist independently to form a chain compound, or the CHₐ group and the CH_{b} group are a group forming a cyclic compound having a ring structure selected from the group consisting of an alicyclic structure, an aromatic ring structure, and a compound ring structure combining them, or
General formula: (H₂ₙCₙ)ₓ₂O(CH)_{y2}(CH₂_{z2}—O_{w2}— (4)
wherein, x2, y2, z2, w2, and n are numbers satisfying x2≥1, y2≥1, z2≥1, w2≥1, and n≥1.

15. The method according to claim 11, wherein
the etching composition further comprises a second additive containing a silane compound having a composition represented by
General formula: Si(R¹¹)(R¹²)(R¹³)(R¹⁴)
wherein R¹¹, R¹², R¹³, and R¹⁴ are monovalent groups, at least one of R¹¹, R¹², R¹³, or R¹⁴ is an alkoxy group, and at least another one of R¹¹, R¹², R¹³ or R¹⁴ is a functional group containing one or more sulfur.

16. The method according to claim 15, wherein
the functional group containing one or more sulfur is a monovalent group containing a thiol group.

17. The method according to claim 15, wherein
the functional group containing one or more sulfur contains a monovalent group having a composition represented by
General formula: (HS)ₓ₃(CH_{c})(CH₂)_{y3}— (3)
wherein, x3, y3, and c are numbers satisfying x3≥1, y3≥1, and C≥0.

18. The method according to claim 11, wherein
a monovalent group other than the alkoxy group and the functional group containing two or more oxygen among the R1, R2, R3, and R4 is a group selected from the group consisting of an alkyl group, a hydroxyl group, and hydrogen.

19. The method according to claim 11, wherein
the silane compound contains 3-trimethoxysilylpropylsuccinic anhydride, 3-trimethoxysilylpropyltrimellitic anhydride, 3-glycidoxypropyltrimethoxysilane, or 3-glycidoxypropylmethyldimethoxysilane.

20. The method according to claim 15, wherein
the silane compound of the second additive contains 3-mercaptopropyltrimethoxysilane.

21. The method according to claim 11, wherein
the film containing silicon nitride are alternately stacked with a film containing silicon oxide to form a stack, and
the film containing silicon nitride in the stack are selectively etched.

22. The method according to claim 21, further comprising:
filling a space formed by the etching of silicon nitride with a metal film.

23. The method according to claim 22, wherein
the stack comprises a columnar portion provided along a stacking direction of the stack, and
the columnar comprises a semiconductor film and a charge storage film disposed between the semiconductor film and the metal film.
